(19) United States
(12) Patent Application Publication
(10) Pub. No.: US 2017/0168099 A1
(43) Pub. Date: Jun. 15, 2017

(54) NON-INVASIVE IMPEDANCE ANALYZING APPARATUS AND METHOD

(71) Applicant: NATIONAL CHENG KUNG UNIVERSITY, Tainan City (TW)

(72) Inventors: Ray-Lee LIN, Tainan City (TW); Wei-Ru CHEN, Tainan City (TW)

(21) Appl. No.: 15/445,597

(22) Filed: Feb. 28, 2017

Related U.S. Application Data
(63) Continuation of application No. 13/927,991, filed on Jun. 26, 2013.

(30) Foreign Application Priority Data
Apr. 19, 2013 (TW) 102113997

(51) Int. Cl. G01R 27/30; G05F 1/46

(52) U.S. Cl. CPC G01R 27/30; G05F 1/46

(57) ABSTRACT

A stability analyzing apparatus is in cooperation with a DC power system having a bus terminal connected to at least a load, and comprises a perturbation signal generating module, a signal processing module and a determining module. The perturbation signal generating module generates a perturbation signal injected into the bus terminal to obtain a transfer function of the bus terminal impedance. The signal processing module is electrically connected to the perturbation signal generating module and calculates the slope of the transfer function of the bus terminal impedance to obtain a transfer function of the bus terminal impedance slope. The determining module is electrically connected to the signal processing module and determines the stability tendency of the DC power system according to the transfer function of the bus terminal impedance slope. A stability analyzing method is also disclosed.

### CROSS REFERENCE TO RELATED APPLICATIONS

This application is a continuation application of U.S. Ser. No. 13/927,991, filed Jun. 26, 2013, which claims priority under 35 U.S.C. §119(a) on Patent Application No(s). 102113997, filed in Taiwan, Republic of China on Apr. 19, 2013, the entire contents of which are hereby incorporated by reference.

### BACKGROUND OF THE INVENTION

Field of Invention

The invention relates to a stability analyzing apparatus and stability analyzing method and, in particular, to a stability analyzing apparatus and stability analyzing method of a direct current (DC) power system.

Related Art

Because the DC power system has advantages of high reliability, good modular design and easy maintenance, it has been widely applied to many appliances, such as a DC grid system or a telecommunication system. For the large-scale DC distributed power system, monitoring the stability thereof is very important in order to avoid potential power failure.

FIG. 1A is a schematic diagram of a DC power system that is equivalent to a dual-port module.

In general, a DC power system will be made equivalent to a dual-port module for monitoring its stability. As shown in FIG. 1A, by a view from the load terminal, the transfer function of the bus terminal impedance Z_{Bus} of the DC power system can be obtained as follows:

$${Z}_{Bus} = \frac{{Z}_{s}}{1 + \frac{{Z}_{s}}{{Z}_{L}}} = \frac{{Z}_{s}}{1 + {T}_{m}}$$

Z_{L} denotes load impedance, Zₛ denotes the impedance of the dual-port power module by a view from the dual-port power module's output terminal, and Tₘ (impedance ratio) denotes the ratio of Zₛ to Z_{L} (i.e. Tₘ=Zₛ/Z_{L}).

According to the transfer function of the bus terminal impedance Z_{Bus}, it can be found that the impedance Z_{Bus} will be approximate to the infinity when the impedance ratio Tₘ equals −1, and therefore the DC power system will become unstable. When the DC power system becomes unstable, some bad influences will be caused, such as higher voltage stress, abnormal system operation or reduced system lifespan.

For monitoring the stability of the DC power system, the impedance ratio Tₘ needs to be analyzed in the conventional art. As shown in FIG. 1B, a perturbation signal iₚ is used and injected into the bus terminal of a DC power system (i.e. injected between the power module and load module), then the ratio of the load terminal current i_{L} flowing into the load module to the output terminal current iₛ of the power module is computed, and thereby the impedance ratio Tₘ can be obtained as follows:

$${T}_{m} = \frac{{Z}_{s}}{{Z}_{L}} = \frac{\frac{{V}_{o}}{{i}_{s}}}{\frac{{V}_{o}}{{i}_{L}}} = \frac{{i}_{L}}{{i}_{s}}$$

However, when the DC power system includes a parallel connection of multiple modules as shown in FIG. 1C, the difficulty in monitoring the stability thereof will increase. FIG. 1C is a schematic diagram of a conventional DC power system 1. The DC power system 1 is a parallel connection of multiple modules, including a plurality of power modules 11 and a plurality of load modules 12. The impedance ratio Tₘ can be obtained by the following equation:

$${T}_{m} = \frac{{Z}_{s}}{{Z}_{L}} = \frac{{i}_{L}}{{i}_{s}} = \frac{{i}_{L 1} + {i}_{L 2} + … + {i}_{LN}}{{i}_{s 1} + {i}_{s 2} + … + {i}_{sN}}$$

The load terminal current i_{L} of the load module includes i_{L1}, i_{L2}, . . . , i_{LN}, and the output terminal current iₛ of the power module includes iₛ₁, iₛ₂, . . . , i_{sN}. Therefore, for monitoring the stability of the DC power system 1, all the load terminal current i_{L} (including i_{L1}, i_{L2}, . . . , i_{LN}) and output terminal current iₛ (including iₛ₁, iₛ₂, . . . , i_{sN}) need to be monitored to compute the impedance ratio Tₘ. However, there is a large number of the power modules 11 and load modules 12, so the complexity and difficulty for monitoring is increased a lot. Besides, this kind of monitoring belongs to an invasive manner, thus forbidden in the practical application.

Therefore, it is an important subject to provide a stability analyzing apparatus and stability analyzing method applied to a DC power system that can simplify the stability monitoring and analyzing of the DC power system to increase the efficiency of the stability analyzing.

### SUMMARY OF THE INVENTION

In view of the foregoing subject, an objective of this invention is to provide a stability analyzing apparatus and stability analyzing method that can simplify the stability monitoring and analyzing of a DC power system for increasing the efficiency of the stability analyzing.

To achieve the above objective, a stability analyzing apparatus according to this invention is in cooperation with a DC power system having a bus terminal connected to at least a load. The stability analyzing apparatus comprises a perturbation signal generating module, a signal processing module and a determining module. The perturbation signal generating module generates a perturbation signal injected into the bus terminal to obtain a transfer function of the bus terminal impedance. The signal processing module is electrically connected to the perturbation signal generating module and calculates the slope of the transfer function of the bus terminal impedance to obtain a transfer function of the bus terminal impedance slope. The determining module is electrically connected to the signal processing module and determines the stability tendency of the DC power system according to the transfer function of the bus terminal impedance slope.

To achieve the above objective, a stability analyzing method according to this invention is in cooperation with a DC power system having a bus terminal connected to at least a load. The stability analyzing method comprises steps of: providing a perturbation signal injected into the bus terminal to obtain a transfer function of the bus terminal impedance; calculating the slope of the transfer function of the bus terminal impedance to obtain a transfer function of the bus terminal impedance slope; and determining the stability tendency of the DC power system according to the transfer function of the bus terminal impedance slope.

In one embodiment, the perturbation signal includes a step current signal or a frequency sweep current signal.

In one embodiment, the step of obtaining the transfer function of the bus terminal impedance further comprises a step of: obtaining a Bode diagram of the bus terminal impedance with different damping ratios of the DC power system according to the transfer function of the bus terminal impedance.

In one embodiment, the step of obtaining the transfer function of the bus terminal impedance slope further comprises a step of: obtaining a Bode diagram of the bus terminal impedance slope with different damping ratios of the DC power system according to the transfer function of the bus terminal impedance slope.

In one embodiment, the Bode diagram of the bus terminal impedance slope includes a gain Bode diagram and a phase Bode diagram.

In one embodiment, when the impedance slope in the gain Bode diagram of the bus terminal impedance slope is larger than 20 dB/decade or less than −20 dB/decade, the DC power system tends to instability.

In one embodiment, when the damping ratio in the Bode diagram of the bus terminal impedance slope is larger than 0.707, the DC power system tends to stability.

In one embodiment, the step of determining the stability tendency of the DC power system further comprises a step of: obtaining a Nyquist diagram of the bus terminal impedance slope with different damping ratios of the DC power system according to the Bode diagram of the bus terminal impedance slope.

In one embodiment, the step of obtaining the Nyquist diagram of the bus terminal impedance slope further comprises a step of: determining the stability tendency of the DC power system according to the Nyquist diagram of the bus terminal impedance slope.

In one embodiment, when the Nyquist contour in the Nyquist diagram of the bus terminal impedance slope exceeds the circle of the damping ratio equal to 0.707, the DC power system tends to instability.

As mentioned above, in the stability analyzing apparatus and method of this invention, a perturbation signal is injected into the bus terminal for obtaining the transfer function of the bus terminal impedance, and then the slope of the transfer function of the bus terminal impedance is calculated for obtaining the transfer function of the bus terminal impedance slope. Subsequently, the stability tendency of the DC power system can be determined according to the transfer function of the bus terminal impedance slope. In comparison with the prior art, the stability tendency of the DC power system can be determined in the invention just by injecting a perturbation signal into the bus terminal, which is a non-invasive method for the stability monitoring. Besides, in the invention, measuring all the output terminal and load terminal currents of the DC power system is not required, and therefore the stability monitoring and analyzing can be simplified a lot and the efficiency of the stability analyzing also can be increased. Besides, in one embodiment of the invention, the stability tendency of the DC power system can be determined by the gain Bode diagram of the bus terminal impedance slope, the phase Bode diagram of the bus terminal impedance slope, or the Nyquist diagram of the bus terminal impedance slope. So, this invention provides a more intuitive manner to determine the stability tendency of the DC power system.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a schematic diagram of a DC power system that is equivalent to a dual-port module;

FIG. 1B is a schematic diagram of a perturbation current injected into the bus terminal of a DC power system;

FIG. 1C is a schematic diagram of a conventional DC power system;

FIG. 2A is a schematic block diagram of a stability analyzing apparatus according to a preferred embodiment of this invention in cooperation with a direct current (DC) power system;

FIG. 2B is a simplified equivalent circuit diagram of the DC power system in FIG. 2A;

FIG. 3 is a flow chart of a stability analyzing method according to a preferred embodiment of this invention;

FIG. 4A is a circuit diagram of a DC power system as an embodiment of this invention;

FIGS. 4B and 4C are tables of the specifications and conditions of the elements of the DC power system in FIG. 4A;

FIG. 5 is a schematic transient response waveform of the output voltage with different load resistances after the perturbation signal is injected into the bus terminal of the DC power system in FIG. 4A;

FIGS. 6A and 6B are respectively a gain Bode diagram and phase Bode diagram of the bus terminal impedance of the DC power system in FIG. 4A with different load resistances;

FIGS. 7A and 7B are gain and phase Bode diagrams of the bus terminal impedance slope obtained by differentiating the Bode diagrams in FIGS. 6A and 6B, respectively;

FIG. 8 is the Nyquist diagram of the bus terminal impedance slope with different load resistances of the DC power system in FIG. 4A;

FIG. 9 is a schematic block diagram of a DC power system according to another embodiment of this invention;

FIG. 10 is a schematic transient response waveform of the output voltage with different load resistances after the perturbation signal is injected into the DC power system in FIG. 9;

FIGS. 11A and 11B are respectively a gain Bode diagram and phase Bode diagram of the bus terminal impedance of the DC power system in FIG. 9 with different load resistances;

FIGS. 12A and 12B are gain and phase Bode diagrams of the bus terminal impedance slope obtained by differentiating the Bode diagrams in FIGS. 11A and 11B, respectively; and

FIG. 13 is the Nyquist diagram of the bus terminal impedance slope with different load resistances of the DC power system in FIG. 9.

### DETAILED DESCRIPTION OF THE INVENTION

The present invention will be apparent from the following detailed description, which proceeds with reference to the accompanying drawings, wherein the same references relate to the same elements.

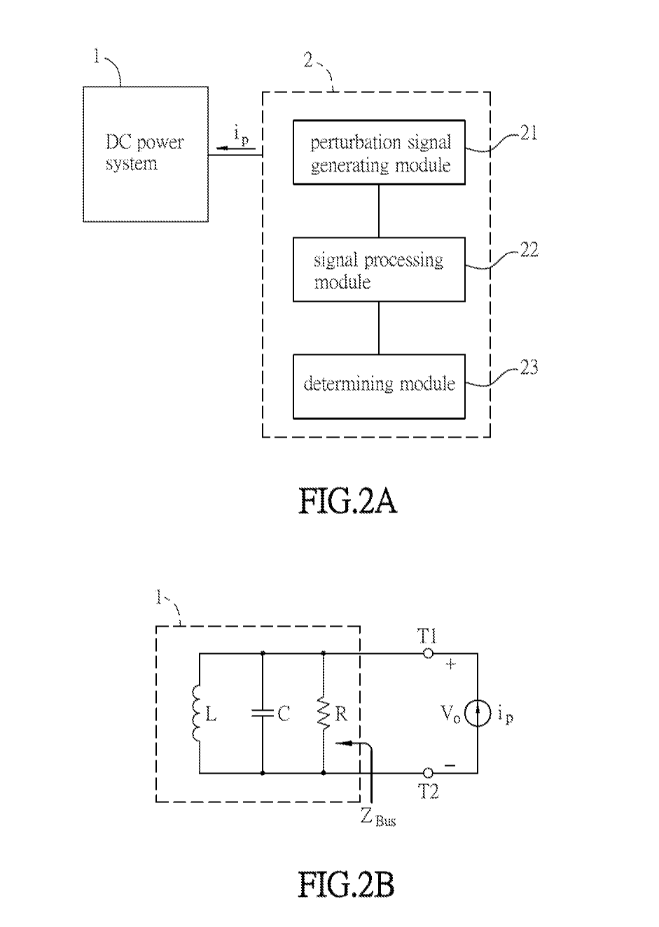

FIG. 2A is a schematic block diagram of a stability analyzing apparatus 2 according to a preferred embodiment of this invention in cooperation with a direct current (DC) power system 1, and FIG. 2B is a simplified equivalent circuit diagram of the DC power system 1 in FIG. 2A.

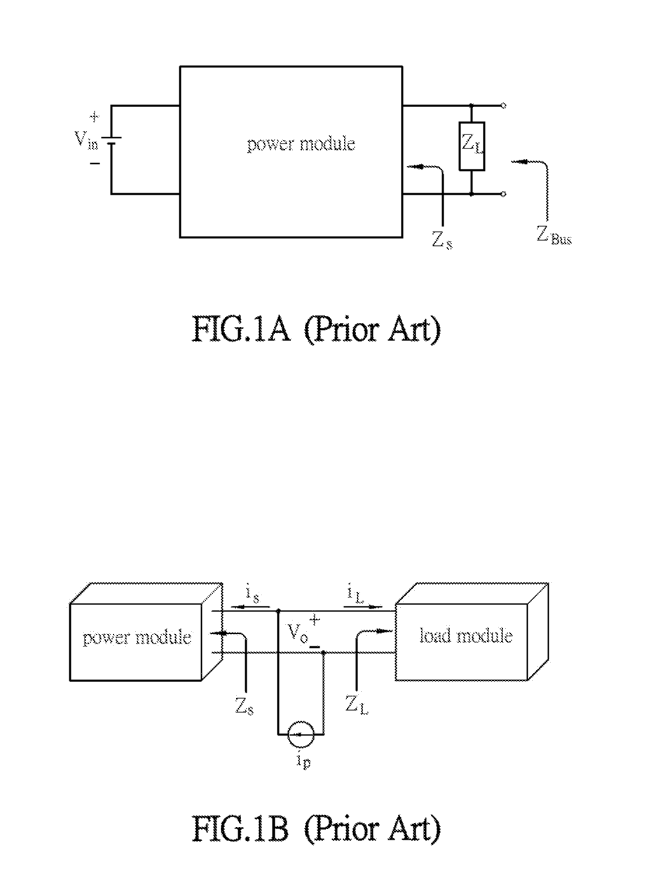

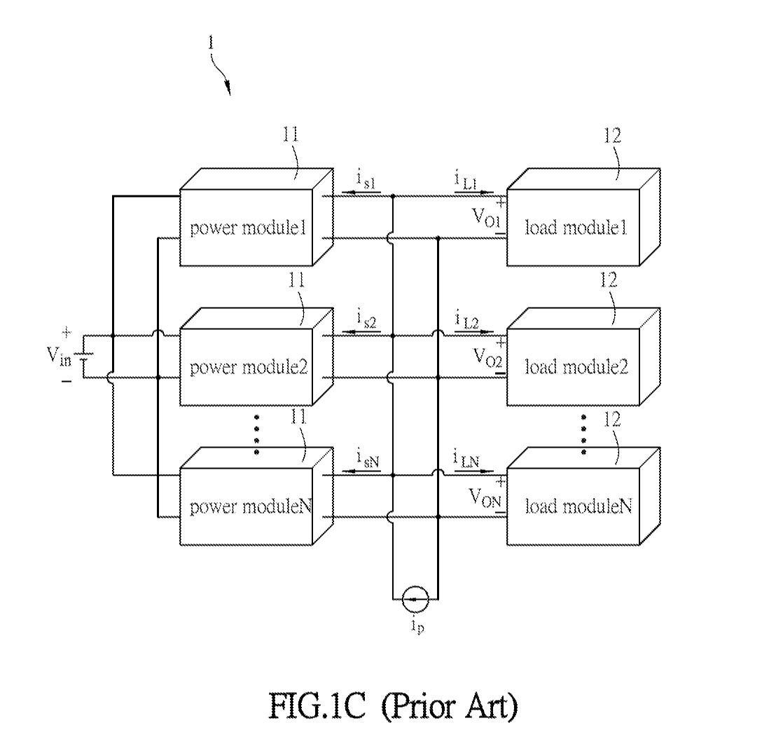

In FIGS. 2A and 2B, the stability analyzing apparatus 2 is in cooperation with the DC power system 1, which includes at least a power module 11 and at least a load module 12 as shown in FIG. 1C. The power module 11 has a power converting circuit that at least has a buck converter, a buck-boost converter, a boost converter or their any combination. In order to conveniently analyze the stability, the above-mentioned converting circuit can be simplified as a parallel RLC loop (i.e. a Norton equivalent circuit) as shown in FIG. 2B, and the parameters thereof can be all derived. The simplified parallel RLC loop has bus terminals T1 and T2, and when a perturbation signal iₚ is injected into the bus terminals T1 and T2, the data of the stability monitoring can be obtained. Besides, in the parallel RLC loop, the transfer function of the bus terminal impedance Z_{Bus}, i.e. the Laplace transfer function of s-domain, can be derived.

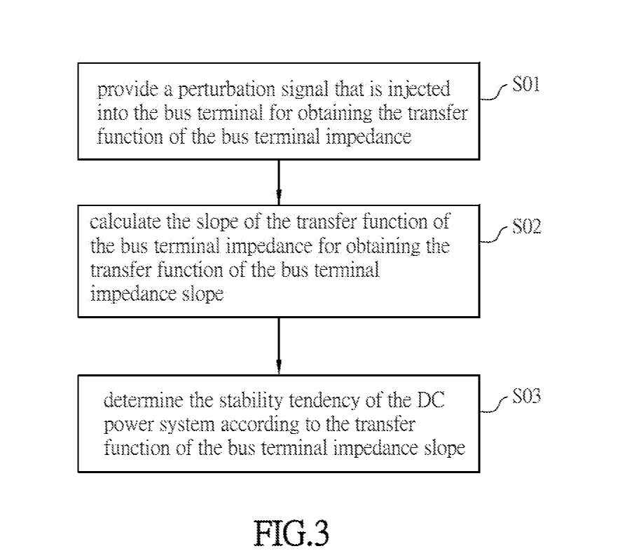

FIG. 3 is a flow chart of a stability analyzing method according to a preferred embodiment of this invention.

The stability analyzing method of this embodiment is applied to the stability analyzing apparatus 2. As shown in FIG. 2A, the stability analyzing apparatus 2 includes a perturbation signal generating module 21, a signal processing module 22, and a determining module 23. The signal processing module 22 is electrically connected to the perturbation signal generating module 21, and the determining module 23 is electrically connected to the signal processing module 22.

The stability analyzing method includes the steps S01 to S03.

The step S01 is to provide a perturbation signal iₚ that is injected into the bus terminals T1 and T2 for obtaining the transfer function of the bus terminal impedance Z_{Bus}. As shown in FIGS. 2A and 2B, the perturbation signal iₚ is generated by the perturbation signal generating module 21 and injected into the bus terminals T1 and T2 of the DC power system 1, and then the signal processing module 22 correspondingly operates to obtain the transfer function of the bus terminal impedance. Herein, the perturbation signal iₚ includes a step current signal or a frequency sweep current signal. The perturbation signal can be, for example but is not limited to, a current source. Therefore, the transfer function of the bus terminal impedance Z_{Bus} can be derived as follows:

$${z}_{Bus} = \frac{L \cdot s}{1 + {T}_{n}} = \frac{L \cdot s}{1 + \frac{\frac{1}{R} + C \cdot s}{\frac{1}{L \cdot s}}}$$

wherein

$${T}_{n} = 2 \cdot ξ \cdot \frac{s}{{ω}_{n}} + \frac{{s}^{2}}{{ω}_{n}^{2}} {ω}_{n} = \frac{1}{\sqrt{L \cdot C}} ξ = \frac{1}{2 \cdot R \cdot \sqrt{\frac{C}{L}}}$$

Tₙ denotes admittance ratio, ξ denotes damping ratio, s=jω, ω denotes angular velocity (w=2π(f), and ωₙ denotes natural resonance frequency.

Besides, the step S01 of obtaining the transfer function of the bus terminal impedance can further include a step of obtaining a Bode diagram of the bus terminal impedance of the DC power system 1 with different damping ratios ζ by the signal processing module 22 according to the transfer function of the bus terminal impedance. Herein, the Bode diagram of the bus terminal impedance includes a gain Bode diagram and a phase Bode diagram. According to the transfer function of the bus terminal impedance, the Bode diagram and Nyquist diagram of the admittance ratio Tₙ and bus terminal impedance Z_{Bus} with different damping ratios ζ can be plotted. The frequency characteristics of the system in the s-domain can be analyzed by the Bode and Nyquist diagrams. By the Bode diagram, the system gain and the phase variation at different frequencies can be found. The Nyquist diagram is a complex plane, and the system's stability can be determined according to the system transfer function (i.e. admittance ratio Tₙ). Besides, by making the absolute value of the admittance ratio Tₙ equal to 1, the crossover frequency can be derived, and also the phase margin PM of the admittance ratio ζ can be obtained. When the damping ratio ζ is larger than 0.707 and the phase margin PM of the admittance ratio Tₙ is larger than 65°, the DC power system 1 tends to stability. The related equations are as follows:

$$\vert {T}_{n} \vert = \sqrt{{( 2 \cdot ξ \cdot \frac{ω}{{ω}_{n}} )}^{2} + {( \frac{{ω}^{2}}{{ω}_{n}^{2}} )}^{2}} = 1 {ω}_{c} = {ω}_{n} \cdot \sqrt{\sqrt{4 \cdot {ξ}^{4} + 1} - 2 \cdot {ξ}^{2}}$$

$${f}_{c} = \frac{{ω}_{n} \cdot \sqrt{\sqrt{4 \cdot {ξ}^{4} + 1} - 2 \cdot {ξ}^{2}}}{2 \cdot π} \begin{matrix}PM = {tan}^{- 1} ( \frac{2 \cdot ξ \cdot \frac{{ω}_{c}^{2}}{{ω}_{n}^{2}}}{\frac{{ω}_{c}^{2}}{{ω}_{n}^{2}}} ) \\ = {tan}^{- 1} ( \frac{2 \cdot ξ}{\sqrt{\sqrt{4 \cdot {ξ}^{4} + 1} - 2 \cdot {ξ}^{2}}} )\end{matrix}$$

Then, the step S02 is to calculate the slope of the transfer function of the bus terminal impedance for obtaining the transfer function of the bus terminal impedance slope. Herein, the slope of the transfer function of the bus terminal impedance is calculated by the signal processing module 22 according to the transfer function of the bus terminal impedance. In other words, the signal processing module 22 differentiates the transfer function of the bus terminal impedance to obtain the transfer function of the bus terminal impedance slope. After differentiating the transfer function of the bus terminal impedance, the transfer function of the bus terminal impedance slope can be obtained as follows:

$$\begin{matrix}{M}_{{Z}_{Bus}} = \frac{d 20 \cdot log \vert \frac{s \cdot L}{1 + {T}_{n}} \vert}{d log f} \\ = 20 \cdot \frac{1 - \frac{{ω}^{4}}{{ω}_{n}^{4}}}{{[ 1 - \frac{{ω}^{2}}{{ω}_{n}^{2}} ]}^{2} + {( 2 \cdot ξ \cdot \frac{ω}{{ω}_{n}^{2}} )}^{2}}\end{matrix}$$

Besides, the step S02 of obtaining the transfer function of the bus terminal impedance slope can further include a step of obtaining a Bode diagram of the bus terminal impedance slope of the DC power system 1 with different damping ratios ζ according to the transfer function of the bus terminal impedance slope. Herein, the Bode diagram of the bus terminal impedance slope of the DC power system 1 with different damping ratios ζ is obtained by the signal processing module 22 according to the transfer function of the bus terminal impedance slope. The Bode diagram of the bus terminal impedance slope includes a gain Bode diagram and a phase Bode diagram.

Then, the step S03 is to determine the stability tendency of the DC power system 1 according to the transfer function of the bus terminal impedance slope. Herein, the stability tendency of the DC power system 1 is determined by the determining module 23 according to the Bode diagram of the bus terminal impedance slope generated by the transfer function of the bus terminal impedance slope. In the Bode diagram of the bus terminal impedance slope, when the impedance slope is larger than 20 dB/decade or less than −20 dB/decade, the DC power system 1 tends to instability. In other words, when the slope of the ascending curve is larger than 20 dB/decade, the system tends to instability. Likewise, when the slope of the descending curve is less than −20 dB/decade, the system also tends to instability. Besides, in the Bode diagram of the bus terminal impedance slope, when the damping ratio ζ is larger than 0.707, the DC power system 1 tends to stability. On the contrary, when the damping ratio ζ is less than 0.707, the DC power system 1 tends to instability. When the maximum slope is larger than 20 dB/decade, the damping ratio ζ is less than 0.707 and the phase margin is less than 65°, and therefore the DC power system 1 tends to instability. Furthermore, the maximum bus terminal impedance slope can be obtained according to the transfer function of the bus terminal impedance slope, and the curve of the maximum bus terminal impedance slope versus the damping ratio ζ can be plotted. When the maximum slop of the impedance curve is larger than 20 dB/decade, the damping ratio ζ is less than 0.707.

The step S03 of determining the stability tendency of the DC power system 1 can further include a step of obtaining a Nyquist diagram of the bus terminal impedance slope of the DC power system 1 with different damping ratios ζ according to the Bode diagram of the bus terminal impedance slope. Herein, the Nyquist diagram of the bus terminal impedance slope with different damping ratios ζ is obtained by the determining module 23. The determining module 23 plots the Nyquist diagram of the bus terminal impedance slope according to the gain Bode diagram and phase Bode diagram of the bus terminal impedance slope. In the Nyquist diagram, different circles denote different damping ratios ζ and different gains. For example, the circle of the damping ratio ζ equal to 0.707 has a radius (gain) equal to 20 dB in this embodiment.

To be noted, in this invention, the stability tendency of the DC power system 1 can be intuitively determined by the Nyquist diagram of the bus terminal impedance slope. In the Nyquist diagram of the bus terminal impedance slope, if the Nyquist contour exceeds the circle of the damping ratio ζ equal to 0.707, the DC power system 1 tends to instability. On the contrary, if the Nyquist contour doesn't exceed the circle of the damping ratio ζ equal to 0.707, the DC power system 1 tends to stability. The stability analyzing method of this invention is further illustrated as below by two practical circuits. However, the stability analyzing method of this invention can be applied to other DC distributed power systems, such as a more complicated power system.

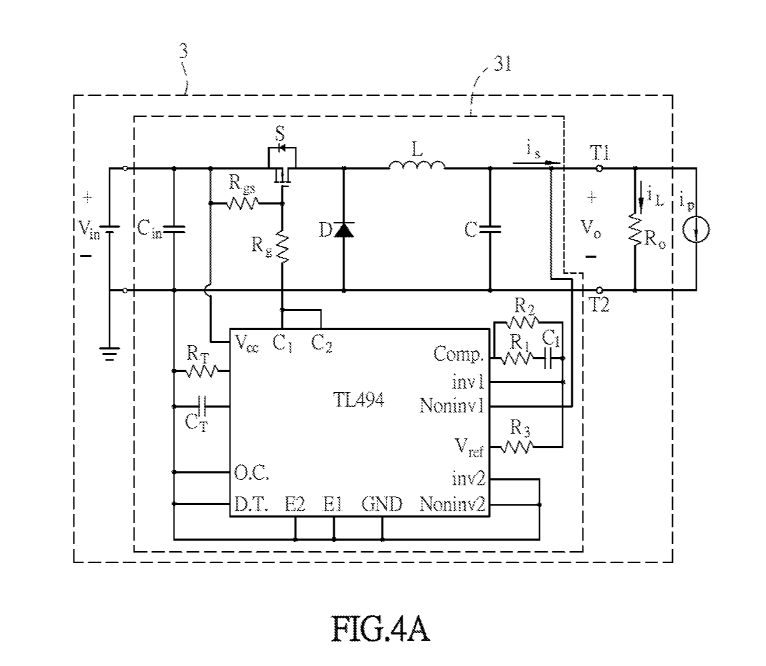

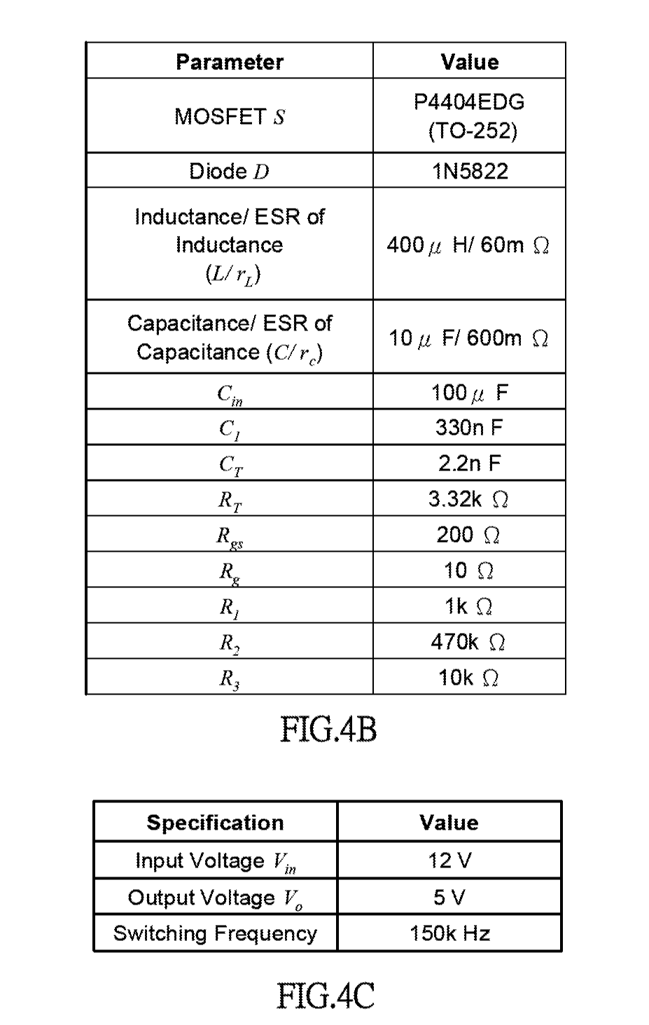

FIG. 4A is a circuit diagram of a DC power system 3 as an embodiment of this invention. The DC power system 3 is a single closed loop circuit, and has a buck converter 31. A load resistance Rₒ is electrically connected to the bus terminals T1 and T2 of the buck converter 31. The load resistance Rₒ of this embodiment is 2.5Ω, or 20Ω for example. FIG. 4A doesn't show the stability analyzing apparatus 2, but just shows that the perturbation signal iₚ generated by the perturbation signal generating module 21 of the stability analyzing apparatus 2 is injected into the bus terminals T1 and T2 of the DC power system 3. Besides, the specifications and conditions of the elements in FIG. 4A can be known by referring to FIGS. 4B and 4C.

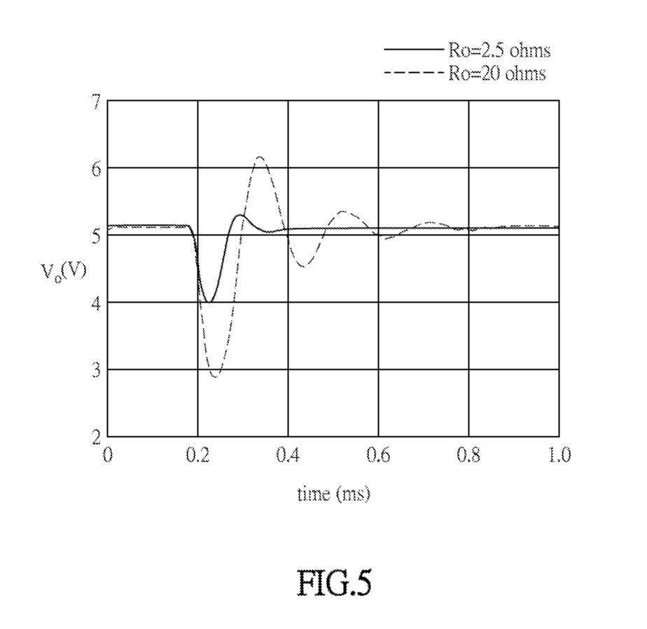

In this embodiment, the perturbation signal iₚ is a step current from 0 A to 1 A. FIG. 5 is a schematic transient response waveform of the output voltage with different load resistance Rₒ after the perturbation signal iₚ (step current) is injected into the bus terminals T1 and T2 of the DC power system 3 in FIG. 4A. By injecting the step current of 0 A˜1 A into the bus terminals T1 and T2 of the DC power system 3, the transient response of the output voltage V_{O} in t-domain can be obtained. From the step response waveform of the output voltage with different load resistances Rₒ (the damping ratio ζ is inversely proportional to the load resistance Rₒ), it can be observed that the overshoot is less and the DC power system 3 tends to stability if the load resistance Rₒ is less (i.e. the damping ratio ζ is larger) and, contrarily, that the overshoot is larger and the DC power system 3 tends to instability if the load resistance Rₒ is larger (i.e. the damping ratio ζ is less). Thus, it can be observed from FIG. 5 that the output voltage V_{O} is larger (6.18V) and the DC power system 3 tends to instability when the load resistance Rₒ equals 20Ω.

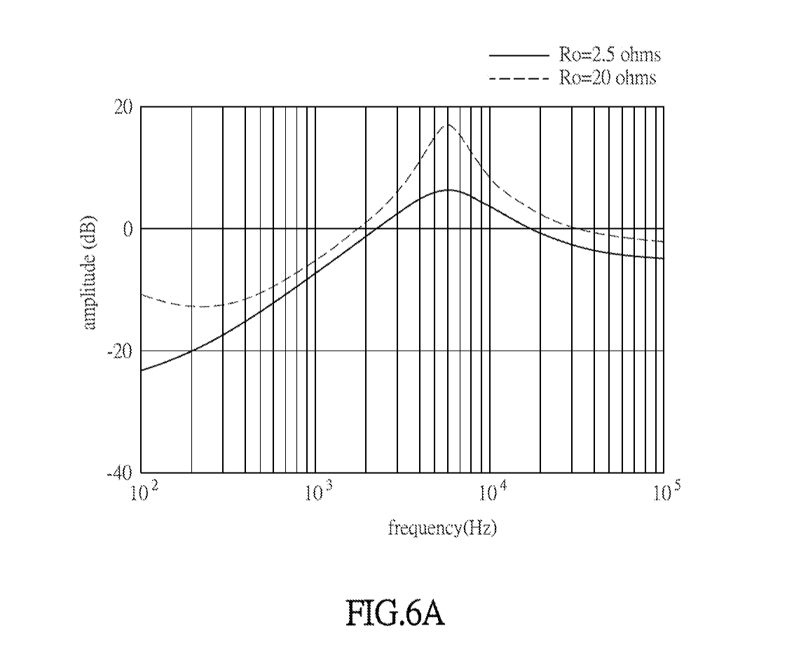

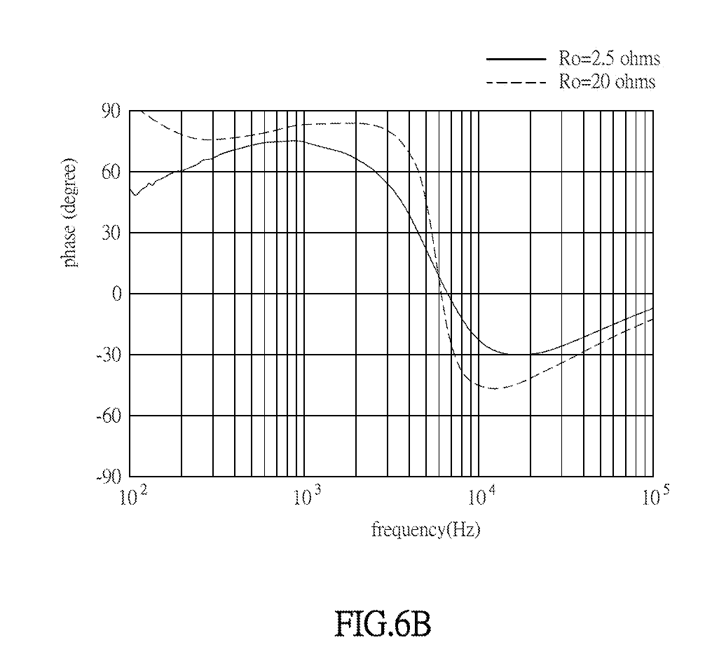

As an embodiment, after the perturbation signal iₚ is injected into the bus terminals T1 and T2 of the DC power system 3, a gain-phase frequency response analyzer (e.g. PSM1735) is used to measure the bus terminals T1 and T2 so as to obtain the transfer function of the bus terminal impedance (s-domain), and thereby the Bode diagram of the bus terminal impedance can be plotted. In other words, in this invention, the frequency response analyzer directly measures the transfer function of the bus terminal impedance, and thus the Bode diagram of the bus terminal impedance can be plotted as shown in FIGS. 6A and 6B. FIG. 6A is a gain Bode diagram of the bus terminal impedance of the DC power system 3 with different load resistances Rₒ, and FIG. 6B is a phase Bode diagram of the bus terminal impedance of the DC power system 3 with different load resistances Rₒ. The abscissa in FIGS. 6A and 6B represents frequency (Hz), and the ordinates in FIGS. 6A and 6B respectively represent gain (dB) and phase (degree).

However, since the stability tendency of the DC power system 3 can not be intuitively known from FIGS. 6A and 6B, the slope (i.e. differential) of the bus terminal impedance is further calculated according to the measured data of the bus terminal impedance. The slope of the transfer function of the bus terminal impedance can be calculated by software, hardware or firmware for obtaining the transfer function of the bus terminal impedance slope, and then the Bode diagram of the bus terminal impedance slope with different load resistances Rₒ of the DC power system 3 can be plotted.

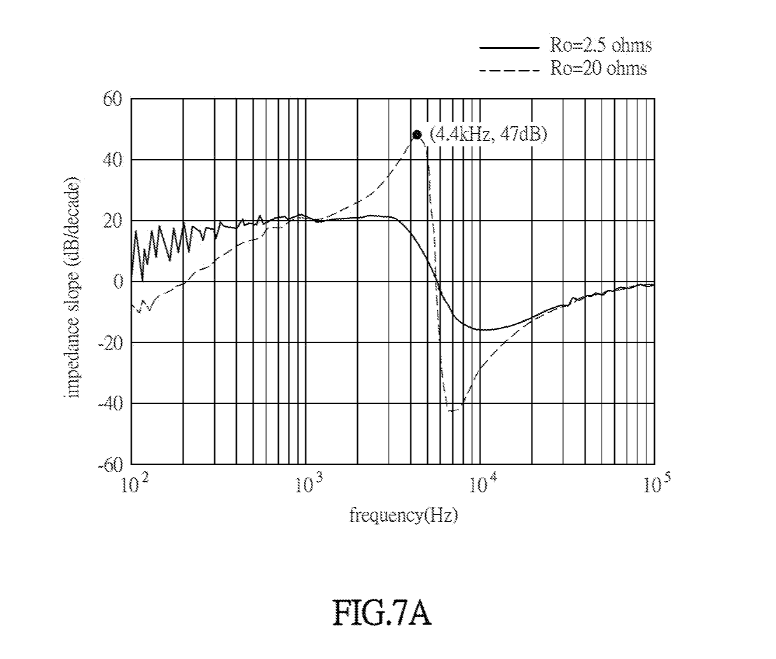

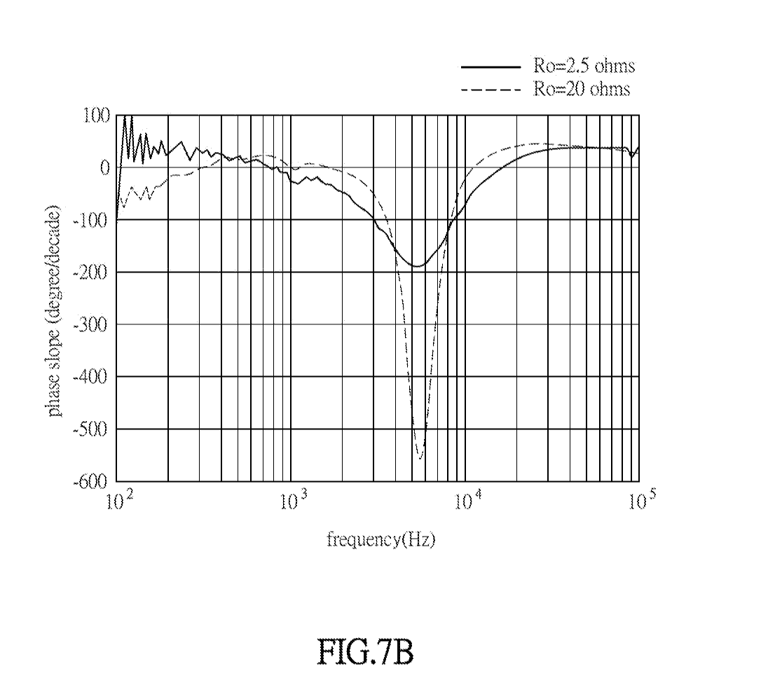

FIGS. 7A and 7B are gain and phase Bode diagrams of the bus terminal impedance slope obtained by differentiating the gain Bode diagram of the bus terminal impedance in FIG. 6A and phase Bode diagram of the bus terminal impedance in FIG. 6B, respectively.

As shown in FIG. 7A, from the impedance slope curve of the load resistance Rₒ equal to 20Ω, it can be known that the maximum impedance slope is 47 dB/decade (at 4.4 kHz), which is far larger than 20 dB/decade. Therefore, when the load resistance Rₒ is 20Ω, the DC power system 3 tends to instability. Thereby, the stability tendency of the DC power system 3 with different load resistance Rₒ can be determined. Besides, with the load resistances Rₒ equal to 2.5Ω and 20Ω respectively, the impedance slope at different frequencies, corresponding damping ratio ζ and phase margin PM of the impedance slope curve can be individually calculated. The following table just shows the maximum impedance slope and its corresponding damping ratio ζ and phase margin PM.

| load resistance Rₒ | 2.5Ω | 20Ω |
|---|---|---|
| maximum slope | 20 dB | 47 dB |
| phase margin PM | >65° | 24.5° |
| damping ratio ζ | >0.707 | 0.46 |

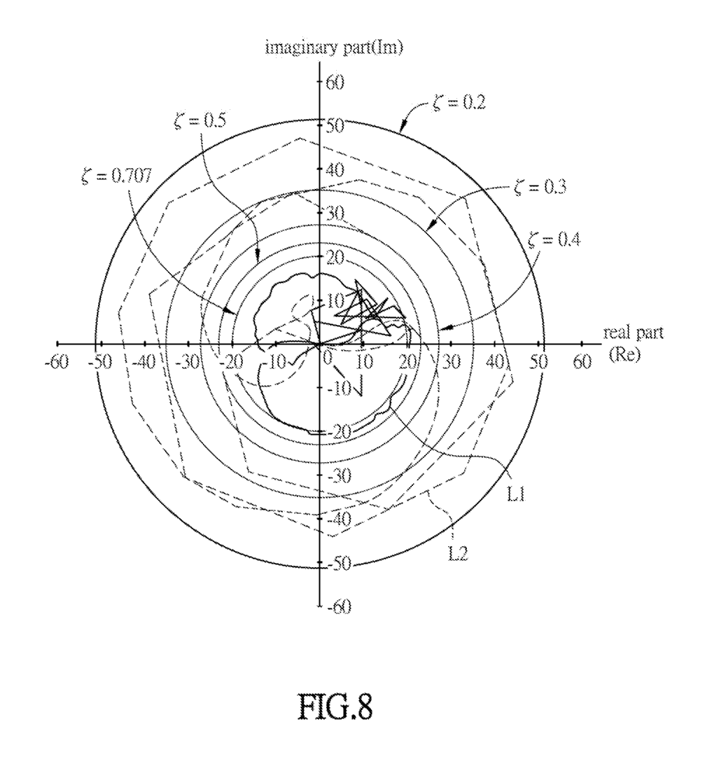

However, for the general users, FIGS. 7A and 7B are still not intuitive sufficiently. Therefore, in this invention, the Nyquist diagram of the bus terminal impedance slope with different load resistance Rₒ of the DC power system 3 is further plotted as shown in FIG. 8 according to the gain Bode diagram of the bus terminal impedance slope in FIG. 7A and the phase Bode diagram of the bus terminal impedance slope in FIG. 7B. In other words, by the obtained impedance slope at different frequencies, corresponding damping ratio ζ and phase margin PM of the impedance slope curve with different load resistances Rₒ, the Nyquist diagram of the bus terminal impedance slope with different load resistances Rₒ can be plotted as shown in FIG. 8, and thereby the stability tendency of the DC power system 3 can be intuitively determined. The Nyquist diagram is a complex plane so the abscissa in FIG. 8 represents a real part (Re) while the ordinate represents an imaginary part (Im). Different damping ratios ζ are corresponding to the circles of different sizes. For example, the circle of the damping ratio ζ equal to 0.707 has a radius (impedance slope) equal to 20 dB/decade, and the rest can be deduced by analogy.

As shown in FIG. 8, in this embodiment, the Nyquist contour (denoted by the line L1) of the bus terminal impedance slope at the load resistances Rₒ equal to 2.5Ω mostly doesn't exceed the circle of the damping ratio ζ equal to 0.707, representing the corresponding damping ratio ζ mostly larger than 0.707 (the maximum impedance slope is less than 20 dB/decade). Therefore, the DC power system 3 will tend to stability. For another case of the load resistances Rₒ equal to 20Ω, since the Nyquist contour (denoted by the line L2) of the bus terminal impedance slope thereof exceeds the circle of the damping ratio ζ equal to 0.707, representing the corresponding damping ratio ζ less than 0.707 (the maximum impedance slope is larger than 20 dB/decade), the DC power system 3 will tend to instability.

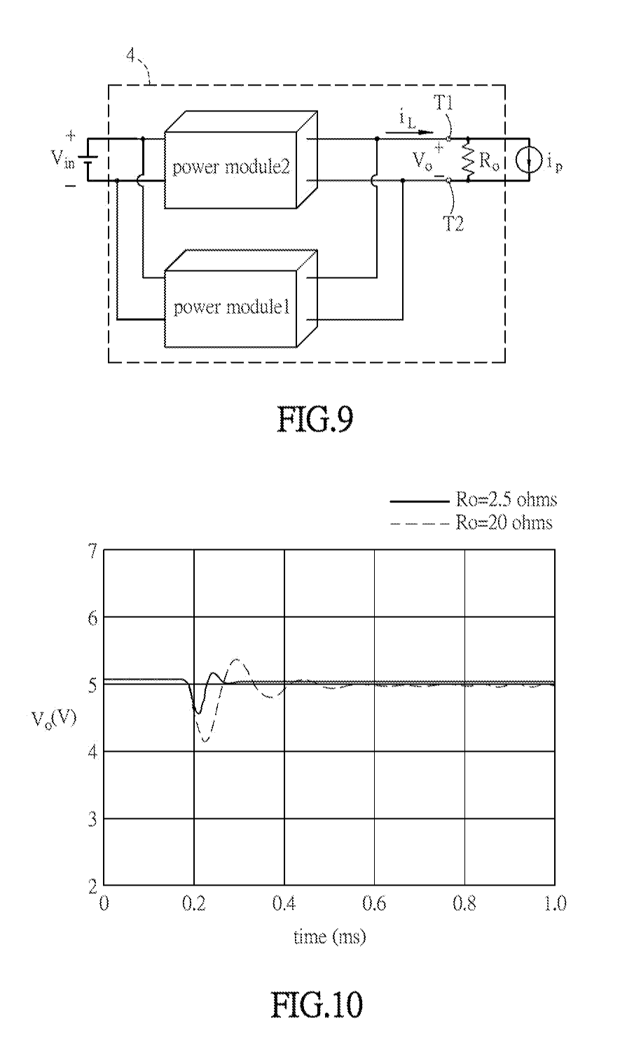

FIG. 9 is a schematic block diagram of a DC power system 4 according to another embodiment of this invention. The DC power system 4 is a parallel connection of two single closed loop DC power systems 3 in FIG. 4A. Herein, FIG. 9 just shows the functional blocks, and the related practical circuit can be understood by referring to FIGS. 4A to 4C. The load resistance Rₒ is also 2.5Ω or 20Ω for example. Besides, the perturbation signal iₚ is also a step current of 0 A˜1 A.

FIG. 10 is a schematic transient response waveform of the output voltage with different load resistance Rₒ after the perturbation signal iₚ is injected into the DC power system 4 in FIG. 9.

By injecting the step current of 0 A˜1 A into the bus terminals T1 and T2 of the DC power system 4, the transient response of the output voltage V_{O} in t-domain can be obtained. From the step response waveform of the output voltage with different load resistances Rₒ (the damping ratio ζ is inversely proportional to the load resistance Rₒ), it can be observed that the overshoot is less and the DC power system 4 tends to stability if the load resistance Rₒ is less (i.e. the damping ratio ζ is larger) and, contrarily, that the overshoot is larger and the DC power system 4 tends to instability if the load resistance Rₒ is larger (i.e. the damping ratio ζ is less).

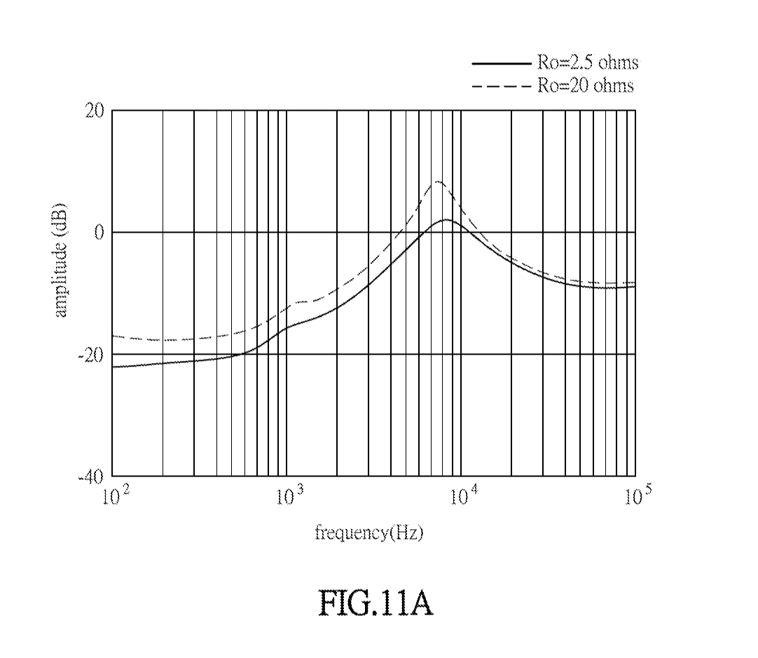

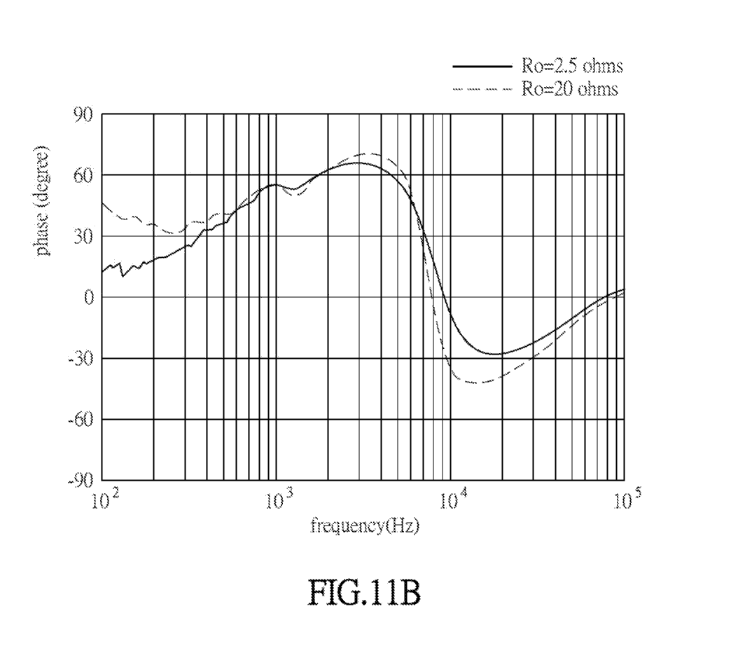

A gain-phase frequency response analyzer (e.g. PSM1735) is used to measure the bus terminals T1 and T2 for obtaining the transfer function of the bus terminal impedance (s-domain), and thereby the Bode diagram of the bus terminal impedance can be plotted as shown in FIGS. 11A and 11B. FIG. 11A is a gain Bode diagram of the bus terminal impedance of the DC power system 4 with different load resistances Rₒ, and FIG. 11B is a phase Bode diagram of the bus terminal impedance of the DC power system 4 with different load resistances Rₒ. However, since the stability tendency of the DC power system 4 can not be intuitively known from FIGS. 11A and 11B, the bus terminal impedance slope is further calculated according to the measured data of the bus terminal impedance. The slope of the transfer function of the bus terminal impedance can be calculated by software, hardware or firmware for obtaining the transfer function of the bus terminal impedance slope, and then the Bode diagram of the bus terminal impedance slope with different load resistances Rₒ of the DC power system 4 can be plotted.

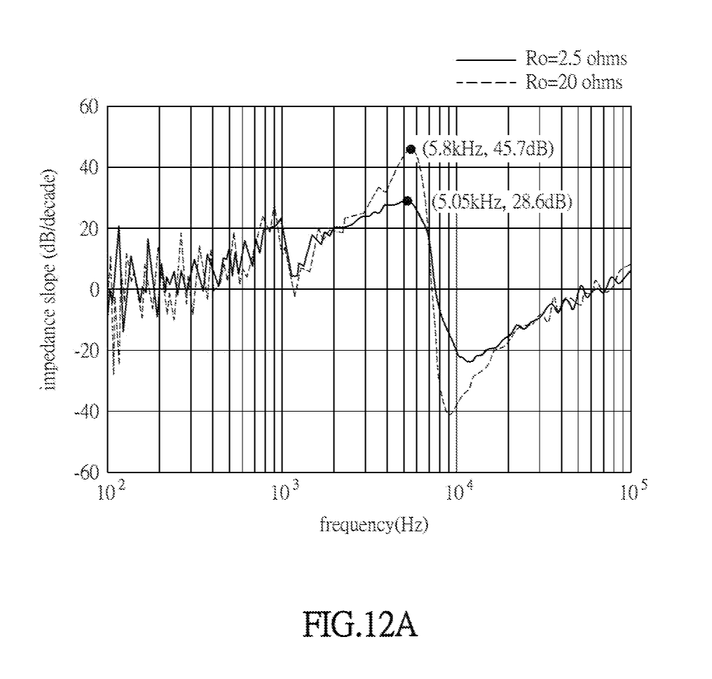

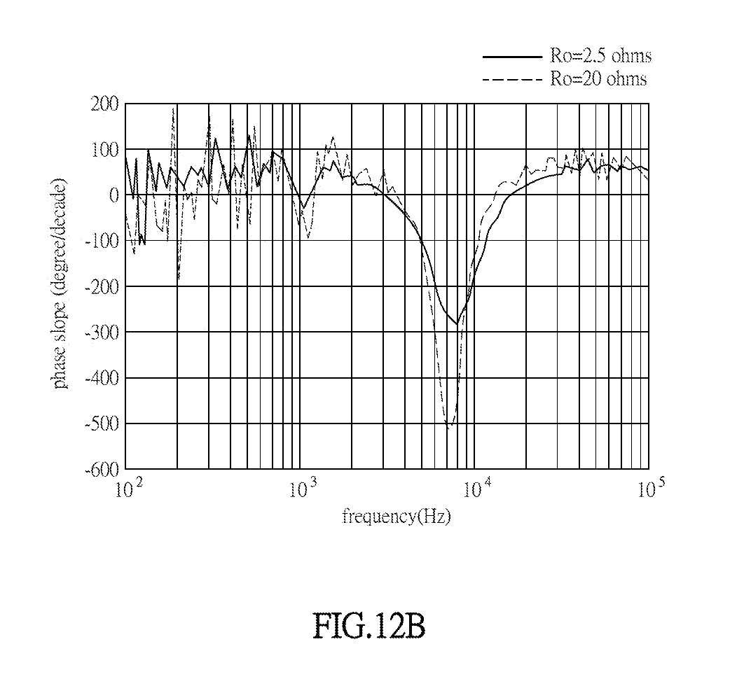

FIGS. 12A and 12B are gain and phase Bode diagrams of the bus terminal impedance slope obtained by differentiating the gain Bode diagram of the bus terminal impedance in FIG. 11A and phase Bode diagram of the bus terminal impedance in FIG. 11B, respectively.

As shown in FIG. 12A, from the impedance slope curves of the load resistance Rₒ equal to 2.5Ω and 20Ω respectively, it can be known that the maximum impedance slopes thereof are 28.6 dB/decade (at 5.05 kHz) and 45.7 dB/decade (at 5.8 kHz), which are far larger than 20 dB/decade. Therefore, when the load resistances Rₒ are 2.5Ω and 20Ω respectively, the DC power system 4 tends to instability. Besides, with the load resistances Rₒ equal to 2.5Ω and 20Ω respectively, the impedance slope at different frequencies, corresponding damping ratio ζ and phase margin PM of the impedance slope curve can be individually calculated. The following table just shows the maximum impedance slope and its corresponding damping ratio ζ and phase margin PM.

| load resistance Rₒ | 2.5Ω | 20Ω |
|---|---|---|
| maximum slope | 28.6 dB | 45.7 dB |
| phase margin PM | 41° | 25.3° |
| damping ratio ζ | 0.38 | 0.23 |

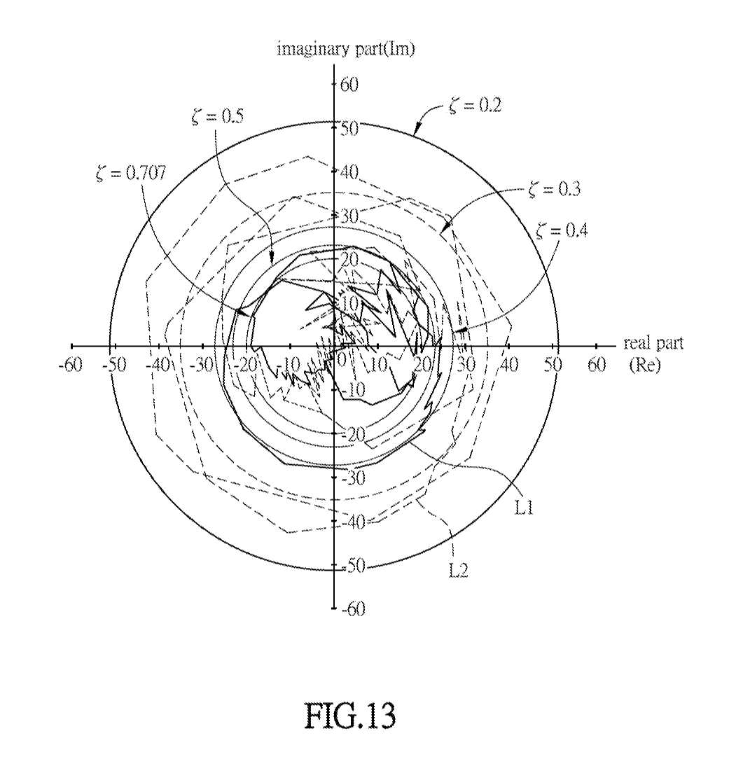

However, for the general users, FIGS. 12A and 12B are still not intuitive sufficiently. Therefore, in this invention, the Nyquist diagram of the bus terminal impedance slope with different load resistance Rₒ of the DC power system 4 can be further plotted as shown in FIG. 13 according to the gain Bode diagram of the bus terminal impedance slope in FIG. 12A and the phase Bode diagram of the bus terminal impedance slope in FIG. 12B. In other words, by the obtained impedance slope at different frequencies, corresponding damping ratio ζ and phase margin PM of the impedance slope curve with different load resistances Rₒ, the Nyquist diagram of the bus terminal impedance slope with different load resistances Rₒ can be plotted as shown in FIG. 13, and thereby the stability tendency of the DC power system 4 can be intuitively determined.

As shown in FIG. 13, in this embodiment, the Nyquist contour (denoted by the line L1) of the bus terminal impedance slope at the load resistances Rₒ equal to 2.5Ω exceeds the circle of the damping ratio ζ equal to 0.707 (with the radius of 20 dB), representing the corresponding damping ratio ζ less than 0.707 (the maximum impedance slope is larger than 20 dB/decade). Therefore, the DC power system 4 will tend to instability. For another case of the load resistances Rₒ equal to 20Ω, since the Nyquist contour (denoted by the line L2) of the bus terminal impedance slope thereof also exceeds the circle of the damping ratio ζ equal to 0.707, representing the corresponding damping ratio ζ less than 0.707 (the maximum impedance slope is larger than 20 dB/decade), the DC power system 4 will also tend to instability.

To be noted, in this invention, no matter how complex the DC power system is and no matter how many DC power systems are connected in parallel to form a DC distributed power system, the transfer function of the bus terminal impedance can be obtained as long as a perturbation signal is injected into the bus terminal of the DC power system. Besides, the transfer function of the bus terminal impedance slope can be further obtained by differentiating the transfer function of the bus terminal impedance. Then, by plotting the Bode diagram (including a gain Bode diagram and a phase Bode diagram) of the bus terminal impedance slope of the DC power system with different damping ratios, the stability tendency of the DC power system can be determined. Furthermore, the Nyquist diagram of the bus terminal impedance slope with different damping ratios of the DC power system can be plotted according to the gain Bode diagram and phase Bode diagram of the bus terminal impedance slope. Then, the stability tendency of the DC power system can be determined just by observing if the impedance slope curve exceeds the circle of the damping ratio equal to 0.707. Therefore, this invention provides a more intuitive manner to determine the stability tendency of the DC power system.

In summary, in the stability analyzing apparatus and method of this invention, a perturbation signal is injected into the bus terminal for obtaining the transfer function of the bus terminal impedance, and then the slope of the transfer function of the bus terminal impedance is calculated for obtaining the transfer function of the bus terminal impedance slope. Subsequently, the stability tendency of the DC power system can be determined according to the transfer function of the bus terminal impedance slope. In comparison with the prior art, the stability tendency of the DC power system can be determined in the invention just by injecting a perturbation signal into the bus terminal, which is a non-invasive method for the stability monitoring. Besides, in the invention, measuring all the output terminal and load terminal currents of the DC power system is not required, and therefore the stability monitoring and analyzing can be simplified a lot and the efficiency of the stability analyzing also can be increased. Besides, in one embodiment of the invention, the stability tendency of the DC power system can be determined by the gain Bode diagram of the bus terminal impedance slope, the phase Bode diagram of the bus terminal impedance slope, or the Nyquist diagram of the bus terminal impedance slope. So, this invention provides a more intuitive manner to determine the stability tendency of the DC power system.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A non-invasive impedance analyzing system configured to be connected with a DC power system including at least a power module and at least a load module through two bus terminals, wherein the DC power system and the non-invasive impedance analyzing system are disposed on the opposite sides of the two bus terminals, and the power module and the load module are disposed on the same side of the two bus terminals, comprising:
a signal generator generating and injecting a step current signal or a frequency sweep current signal into the bus terminals in a parallel manner;
a frequency analyzer obtaining a transfer function of the bus terminal impedance of the bus terminals of frequency domain by obtaining an output voltage in response to the injected step current signal or frequency sweep current signal when the step current signal or the frequency sweep current signal is injected into the bus terminals, without measuring at least one of a current of the power module and a current of the load module; and
a signal processing device calculating the slope of the transfer function of the bus terminal impedance to obtain a transfer function of the bus terminal impedance slope, and obtaining a Bode diagram of the bus terminal impedance slope with different damping ratios of the DC power system according to the transfer function of the bus terminal impedance slope.

2. The non-invasive impedance analyzing system as recited in claim 1, wherein the Bode diagram of the bus terminal impedance slope includes a gain Bode diagram and a phase Bode diagram.

3. The non-invasive impedance analyzing system as recited in claim 1, wherein the DC power system is determined to tend to instability when the impedance slope in the Bode diagram of the bus terminal impedance slope is larger than a first threshold value or less than a second threshold value, or the DC power system is determined to tend to stability when the impedance slope in the Bode diagram of the bus terminal impedance slope is between the first threshold value and the second threshold value, the first threshold value is 20 dB/decade, and the second threshold value is −20 dB/decade.

4. The non-invasive impedance analyzing system as recited in claim 1, wherein when the damping ratio in the Bode diagram of the bus terminal impedance slope is larger than 0.707, the DC power system tends to stability.

5. The non-invasive impedance analyzing system as recited in claim 1, wherein the signal processing device further obtains a Nyquist diagram of the bus terminal impedance slope with different damping ratios of the DC power system according to the Bode diagram of the bus terminal impedance slope, a display of the non-invasive impedance analyzing system plots the Nyquist diagram of the bus terminal impedance slope with different damping ratios of the DC power system according to the Bode diagram of the bus terminal impedance slope, and plots a circle of a reference damping ratio, wherein the DC power system is determined to tend to instability if the impedance slope curve in the Nyquist diagram exceeds the circle of the reference damping ratio, or the DC power system is determined to tend to stability if the impedance slope curve in the Nyquist diagram does not exceed the circle of the reference damping ratio.

6. The non-invasive impedance analyzing system as recited in claim 5, wherein the reference damping ratio is equal to 0.707.

7. A non-invasive impedance analyzing method configured to be applied to a DC power system including at least a power module and at least a load module through two bus terminals, wherein the load module are disposed on the same side of the two bus terminals, comprising steps of:
providing a step current signal or a frequency sweep current signal injected into the bus terminals in a parallel manner to obtain a transfer function of the bus terminal impedance of the bus terminals of frequency domain by obtaining an output voltage in response to the injected step current signal or frequency sweep current signal by a frequency analyzer, without measuring at least one of a current of the power module and a current of the load module;
calculating the slope of the transfer function of the bus terminal impedance to obtain a transfer function of the bus terminal impedance slope; and
obtaining a Bode diagram of the bus terminal impedance slope with different damping ratios of the DC power system according to the transfer function of the bus terminal impedance slope.

8. The non-invasive impedance analyzing method as recited in claim 7, wherein the Bode diagram of the bus terminal impedance slope includes a gain Bode diagram and a phase Bode diagram.

9. The non-invasive impedance analyzing method as recited in claim 7, wherein the DC power system is determined to tend to instability when the impedance slope in the Bode diagram of the bus terminal impedance slope is larger than a first threshold value or less than a second threshold value, or the DC power system is determined to tend to stability when the impedance slope in the Bode diagram of the bus terminal impedance slope is between the first threshold value and the second threshold value, the first threshold value is 20 dB/decade, and the second threshold value is −20 dB/decade.

10. The non-invasive impedance analyzing method as recited in claim 7, wherein when the damping ratio in the Bode diagram of the bus terminal impedance slope is larger than 0.707, the DC power system tends to stability.

11. The non-invasive impedance analyzing method as recited in claim 7, further comprising steps of:
obtaining a Nyquist diagram of the bus terminal impedance slope with different damping ratios of the DC power system according to the Bode diagram of the bus terminal impedance slope;
plotting the Nyquist diagram of the bus terminal impedance slope with different damping ratios of the DC power system according to the Bode diagram of the bus terminal impedance slope; and
plotting a circle of a reference damping ratio, wherein the DC power system is determined to tend to instability if the impedance slope curve in the Nyquist diagram exceeds the circle of the reference damping ratio, or the DC power system is determined to tend to stability if the impedance slope curve in the Nyquist diagram does not exceed the circle of the reference damping ratio.

12. The non-invasive impedance analyzing method as recited in claim 11, wherein the reference damping ratio is equal to 0.707.
